(19) United States
(12) Patent Application Publication
(10) Pub. No.: US 2009/0307551 A1
(43) Pub. Date: Dec. 10, 2009

(54) Mixed Signal Circuit for an Electronic Protected Control or Regulation System

(76) Inventors: Wolfgang Fey, Niedernhausen (DE); Manfred Kulesch, Ingolstadt (DE); Frank Michel, Rosbach v.d.Hohe (DE)

Correspondence Address: CONTINENTAL TEVES, INC., ONE CONTINENTAL DRIVE, AUBURN HILLLS, MI, 48326-1581, US

(21) Appl. No.: 12/092,100

(22) PCT Filed: Oct. 31, 2006
(86) PCT No.: PCT/EP06/67963

§ 371 Date: Sep. 5, 2008

(30) Foreign Application Priority Data
Nov. 3, 2005 (DE) 10 2005 052 914.3
Oct. 31, 2006 (DE) 10 2006 051 907.8

(51) Int. Cl. H03M 13/00; G06F 11/07

(52) U.S. Cl. 714/746; 714/E11.023; 714/799

(57) ABSTRACT

Mixed signal circuit (4, 4′) for an electronic, protected control or regulation system, including a connecting bus for the connection of an external module (9, 9′) and one or more external and/or internal sensor inputs (2, 2′) for the connection of sensor modules, in which case the inputs can receive sensor data as well as test data (14, 15) which safeguard the sensor data, and in which case the test data being used on the input side for safeguarding the sensor data are also used internally for safeguarding the sensor data which are reprocessed internally.

The invention furthermore relates to a data transmission method with several data transmission steps (18, 18′, 16, 16′, 6, 6′, 7, 7′, 8, 8′) as well as to the use of the above mixed signal circuit in an electronic, protected motor vehicle control or regulation system.

### BACKGROUND OF THE INVENTION

The present invention relates to a mixed signal circuit including a connecting bus (16) for connecting an external module (11, 11′), one or more sensor inputs (2, 2′) for connection of one or more sensor modules. The inputs can receive sensor data as well as test data (14, 15) which safeguard the sensor data, and one or more output interfaces (16, 16′) on the output side for the connection of one or more external modules (9, 9′). The test data being used on the input side for safeguarding the sensor data are output also during the submission on the output side to the one or more additional external modules (9, 9′) for safeguarding the data submitted, and/or the test data used on the input side for safeguarding the sensor data are used within the mixed signal circuit for safeguarding the sensor data being reprocessed internally.

The present invention also relates to a method including several data transmission steps (18, 18′, 16, 16′, 6, 6′, 7, 7′, 8, 8′) in which data which are generated in one or more sensors (2, 2′) are transmitted to an evaluation unit (11, 11′), and/or in which data from the evaluation unit are transmitted to one or more actors, in which case a data processing module (4, 4′) is arranged in the data transmission path between actor/sensor and evaluation unit, which groups and/or pre-processes the data of the one or more sensors/actors, and in which case test data are processed within the data processing module which are used to safeguard the data transmitted from/to the sensor/actor and/or to safeguard the data transmitted from/to the evaluation unit.

Equal test data are transmitted or jointly transmitted at least in the data transmission steps (18′) from/to sensor/actor to/from data processing module and the data transmission steps (16′) from/to data processing module to/from evaluation unit.

Motor vehicle brake control units equipped with ABS, ESP, etc. which comprise a fail-safe microcontroller (e.g. built up in two-core microprocessor technology) and an integrated mixed signal circuit as the core of the electronics are per se known in the art. The separation of the microcontroller equipped with the microprocessor system from the mixed signal chip is required in order to be able to manufacture power drivers for the actuation of e.g. the valve coils of an ABS system in the semiconductor technology employed likewise in an integrated type of construction.

Apart from the power drivers, the processing of input signals for the sensors connected to the control unit is also grouped within the mixed signal circuit. Output units for the actors connected to the control unit are also grouped in the mixed signal circuit in addition to the sensor input data processing.

Due to the high safety demands placed on a control unit for motor vehicles, especially when employed as a brake control unit, it is necessary to examine the correctness of the data being transmitted from one integrated electronic component to another electronic component, for example from the sensors to the microcontroller. For this purpose, test data which permit safeguarding the sensor data transmitted are used in the generic circuit.

The control units described above involve the shortcoming that the measures taken as a safeguard of such data being transmitted through external interfaces do not cover the entire signal path.

In view of the above, an object of the invention at topic involves improving the safety of the data transmission path between electronic modules (e.g. electronic components) in a motor vehicle control unit, in particular from a sensor to a microcontroller.

### SUMMARY OF THE INVENTION

According to the invention, this object is achieved by the mixed signal circuit including a connecting bus (16) for connecting an external module (11, 11′), one or more sensor inputs (2, 2′) for connection of one or more sensor modules. The inputs can receive sensor data as well as test data (14, 15) which safeguard the sensor data, and one or more output interfaces (16, 16′) on the output side for the connection of one or more external modules (9, 9′). The test data being used on the input side for safeguarding the sensor data are output also during the submission on the output side to the one or more additional external modules (9, 9′) for safeguarding the data submitted, and/or the test data used on the input side for safeguarding the sensor data are used within the mixed signal circuit for safeguarding the sensor data being reprocessed internally.

In a first alternative, it is provided in the mixed signal circuit according to the invention to use the test data which are used on the input side for safeguarding the sensor data, also in the submission to additional external modules in order to safeguard the data submitted. Such data is then used as well in the external module for testing the data transmitted to the module.

According to a second alternative of the invention, it is arranged for that the test data used on the input side for safeguarding the sensor data are used within the mixed signal circuit for safeguarding the sensor data being reprocessed internally.

Compared to the prior art mixed signal circuit, it is hence preferred not to generate test data in addition, at least in the event of fail-free transmission. The generation of test data rather takes place basically only within the sensor. It is especially suitable when the test data are generated, if possible, at the beginning of the signal transmission chain that means especially in the area of the sensor head or the sensor element.

The invention also relates to a data transmission method including several data transmission steps (18, 18′, 16, 16′, 6, 6′, 7, 7′, 8, 8′) in which data which are generated in one or more sensors (2, 2′) are transmitted to an evaluation unit (11, 11′), and/or in which data from the evaluation unit are transmitted to one or more actors, in which case a data processing module (4, 4′) is arranged in the data transmission path between actor/sensor and evaluation unit, which groups and/or pre-processes the data of the one or more sensors/actors, and in which case test data are processed within the data processing module which are used to safeguard the data transmitted from/to the sensor/actor and/or to safeguard the data transmitted from/to the evaluation unit. Equal test data are transmitted or jointly transmitted at least in the data transmission steps (18′) from/to sensor/actor to/from data processing module and the data transmission steps (16′) from/to data processing module to/from evaluation unit.

Further preferred embodiments can be seen in the following description.

The invention will now be explained in detail by way of example making reference to the Figures.

### BRIEF DESCRIPTION OF THE DRAWINGS

In the accompanying drawing:

FIG. 1 is a schematic representation of a mixed signal circuit according to the state of the art; and

FIG. 2 is likewise a schematic representation of a mixed signal circuit according to the invention.

### DETAILED DESCRIPTION OF THE DRAWINGS

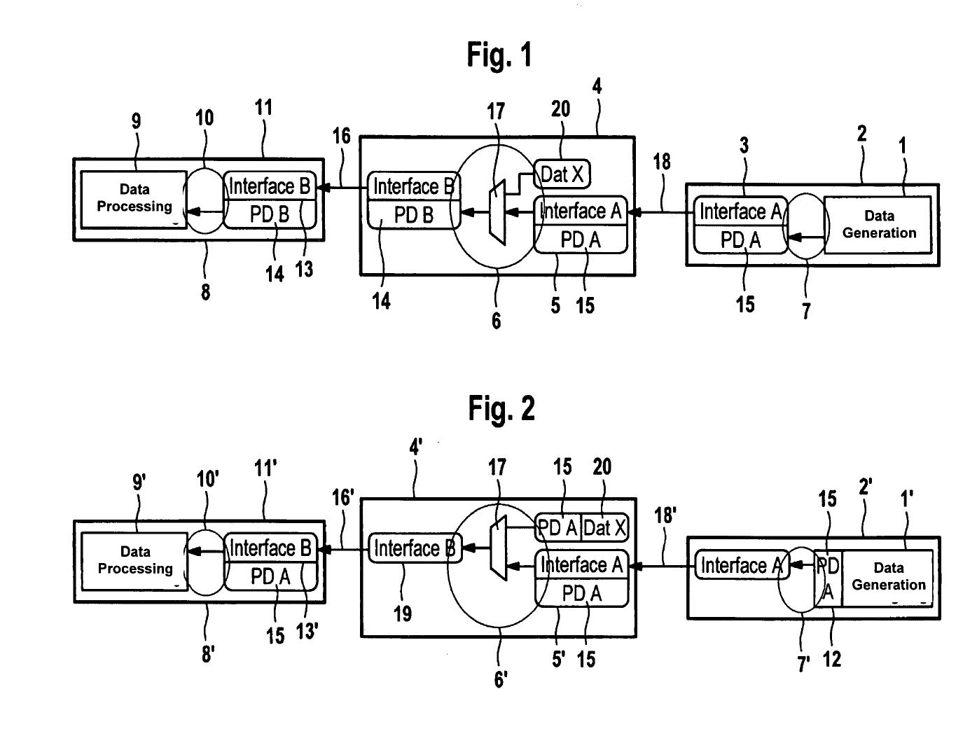

In FIG. 1, sensor 2 is connected via data bus 18 to mixed signal circuit 4. Sensor 2 comprises a data source 1 and an interface ‘interface A’ 3 for the output and transmission of digital sensor data. The sensor data produced by sensor 2 are transmitted via line 18 to mixed signal circuit 4. While the internal data transmission of sensor 4 (marked symbolically by a circle as data path 7) is not protected, the sensor data transmitted via bus 18 are safeguarded by additional test data ‘PD A’ 15. Test data 15 render it possible to detect transmission errors on the input side of circuit 4 and to correct the data, in case of need, prior to the internal reprocessing operation.

Consequently, mixed signal circuit 4 checks in particular in input circuit 5 the input data transmitted by sensor 2 with the aid of the test data which are transmitted as well. When there is conformity of data, data are submitted to the internal bus 6. Bus 6 marked by a circle, in the example illustrated herein, substitutionally represents symbolically a multiplexer 17 for the realization of several sensor inputs, in which case test data are not transmitted via bus 6. In the case of an error during the receipt of sensor data as described hereinabove, an error message is generated which is also made available without test data to the internal bus 6. The symbol ‘Dat X’ 16 which is likewise connected on the input side to internal bus 6 is substitutional for additional, non-sensory or internal data of the mixed signal circuit which can also be output using bus 16.

In addition to sensor(s) 2, microcontroller 11 is also connected to mixed signal circuit 4, reading the sensor data conveyed by the mixed signal circuit into input interface 13 via SPI data bus 16.

To safeguard the transmission of data from mixed signal circuit 4 to microcontroller 11, again test data ‘PD B’ 14 are generated in the mixed signal circuit 4 according to the state of the art and transmitted jointly with the sensor data via BUS 16 to microcontroller 11.

Consequently, three areas of the signal path from sensor 2 to microcontroller 11 as illustrated in FIG. 1 are not protected by test data, with the result that any errors possibly occurring there cannot be detected.
Internal bus 7 in sensor 2,
Internal bus 6 and internal data ‘Dat X’ 20 in mixed signal circuit 4, and
Internal bus 10 in microcontroller 11.

FIG. 2 shows a schematic representation of an improved signal path from sensor 2′ to microcontroller 11′ via mixed signal circuit 4′, in which the above-mentioned sources of error are prevented.

For this purpose, a test data generation device for the generation of test data 12 is provided inside sensor 2′ already in the area of the data generation 1′ (for example, directly adjacent to a sensory element). Data testing with the test data takes place in the input of mixed signal circuit 4′ as is described in connection with FIG. 1. In contrast to the mixed signal circuit 4 in FIG. 1, the sensor data, when they were error-free, including the equal test data generated already in sensor 2′ are then transmitted to internal bus 6′. If the data contained an error, an error message and a check sum matching the error message are generated corresponding to the circuit in FIG. 1. The error message and the generated check sum are submitted to internal bus 6′.

Subsequently, the sensor data upon request of microcontroller 11′ can be output to the latter by way of bus 16 jointly with the test data originating from sensor 2′. However, in case the data do not contain test data or are not provided with test data prior to being output by the data output interface 19, a new calculation of new test data is performed corresponding to the circuit in FIG. 1.

Examples of data to be submitted, which do not dispose of test data, are e.g. non-protected internal data (‘Dat X’) of an analog/digital converter which is positioned within mixed signal circuit 4′, or data from sensors which were faulty and have been corrected in the mixed signal circuit 4′. It is, however, arranged in the illustrated example of FIG. 2 that likewise the internal data ‘Dat X’ 20 are provided with test data 15 directly in the area of data generation.

Input interface 13′ of microcontroller 11′ receives the data and test data being output by mixed signal circuit 4′ by way of bus 16′ and issues an error message if data and test data are not in conformity with each other.

The test data (e.g. parity, CRC (Cyclic Redundancy Checksum), etc.) are preferably generated according to a per se known parity or CRC method.

Corresponding to the example in FIG. 2, the data within microcontroller 11′ are processed in a non-protected fashion or in a way protected by means of other test data. It is, however, especially appropriate if also within microcontroller 8′ the inventive principle of the complete test data passage from data generation to data utilization in block 9′ is continued consistently, in particular in an internal transmission of data via bus 10′. The precondition is that a data processing operation performed within microcontroller 11′ also makes use of the test data which have been generated already in another component.

As has been explained already hereinabove, the data transmission concept in FIG. 2 is laid out in such a way that the same data together with the same test data are tested several times on the signal path from sensor 2′ via mixed signal circuit 4′ to microcontroller 11′. To this end, each receiving device 13′ and 5′ is designed in such a fashion that it can test the test data and can output a corresponding error signal when there is an error. The corresponding error signals can be output, for example as an error word, either via an error line or via the bus itself. It is especially expedient to use different error words to this end so that the type and/or the location of the error can be determined. It is quite particularly suitable in this connection if appropriate test data are then transmitted with regard to the error word to be submitted, which test data in turn allow testing the transmitted error word.

Another preferred possibility of protecting the entire data path in principle also consists in basically maintaining the test data, while, however, considering the test data prior to each transmission as a block of useful data and test data and by extending them by additional test data.

Only the signal transmission path from sensor to microcontroller has been described in the example described hereinabove. Similarly, however, the invention also relates to a transmission from a microcontroller to a sensor or actor, which is safeguarded in a corresponding manner in the reverse direction of signals and can prevail at the same time or as an alternative.

According to an example of the invention not shown, the mixed signal circuit can be grouped with the microcontroller to form a joint electronic component or chip.

1-10. (canceled)

11. A mixed signal circuit (4, 4′) for an electronic, protected control system, comprising:
a connecting bus (16) for connecting an external module (11, 11′);
one or more sensor inputs (2, 2′) for connecting one or more sensor modules, wherein the inputs can receive sensor data as well as test data (14, 15) which safeguard the sensor data;
one or more output interfaces (16, 16′) on an output side for connecting one or more external modules (9, 9′), wherein the test data being used on the input side for safeguarding the sensor data are output on the output side to one or more additional external modules (9, 9′) for safeguarding the data submitted, or the test data used on the input side for safeguarding the sensor data are used within the mixed signal circuit for safeguarding the sensor data being reprocessed internally.

12. A circuit as claimed in claim 11, wherein an input-side error correction device is provided which, upon detection of a data error on the input side, uses the test data to perform an error correction if the prevailing complexity of errors allows doing so.

13. A circuit as claimed in claim 11, further comprising at least one multiplexer (17) which reduces a number of sensor channels which extend into the mixed signal circuit on the input side and comprise the sensor data and the associated test data, to a lower number of channels, in which case additional data inputs which originate from one or more internal data sources (20) can exist in particular at the data input of the multiplexer.

14. A circuit as claimed in claim 11, further comprising an error word generator which in the case of and in dependence on the type of an error generates for each error an individual error word for characterizing the error or the location of the error.

15. A circuit as claimed in claim 11, wherein the data and test data transmitted to the external module(s) and, as the case may be, error words are transmitted to the external module by way of an SPI data bus (16′).

16. A data transmission method comprising:
two or more data transmission steps (18, 18′, 16, 16′, 6, 6′, 7, 7′, 8, 8′) for transmitting data that is generated in one or more sensors (2, 2′) to an evaluation unit (11, 11′), or for transmitting data from the evaluation unit to one or more actors, wherein a data processing module (4, 4′) is arranged in the data transmission path and groups or pre-processes the data, wherein test data is processed within the data processing module which are used to safeguard the data transmitted, and equal test data is transmitted in the data transmission steps (18′).

17. A data transmission method as claimed in claim 16, wherein the same test data as the test data being used in the transmission are used in the data transmission steps within the data processing module (6′) for the processing of the sensor data or the actor data.

18. A data transmission method as claimed in claim 16, wherein the test data are generated in the area of the data generation (1′, 15) that is as early as possible in the signal path.

19. A system comprising:
a mixed signal circuit (4, 4′) for an electronic, protected control system, having a connecting bus (16) for connecting an external module (11, 11′), one or more sensor inputs (2, 2′) for connecting one or more sensor modules, wherein the inputs can receive sensor data as well as test data (14, 15) which safeguard the sensor data, one or more output interfaces (16, 16′) on an output side for connecting one or more external modules (9, 9′), wherein the test data being used on the input side for safeguarding the sensor data are output on the output side to one or more additional external modules (9, 9′) for safeguarding the data submitted, or the test data used on the input side for safeguarding the sensor data are used within the mixed signal circuit for safeguarding the sensor data being reprocessed
a microcontroller module (9, 9′), wherein the microcontroller and the mixed signal circuit (4, 4′) connected are connected via a bus, wherein one or more sensor inputs for the connection of sensor modules (2, 2′) are provided.

20. A system as claimed in claim 19, wherein the circuit is used for the regulation of brake systems or for the control of passive safety systems such as an airbag or seat belt pretensioning systems.
